(19) United States
(12) Patent Application Publication
(10) Pub. No.: US 2008/0123305 A1
(43) Pub. Date: May 29, 2008

(54) Multi-channel memory modules for computing devices

(75) Inventors: Hossein Amidi, Lake Forest, CA (US); Satyadev Kolli, Milpitas, CA (US)

Correspondence Address: PERKINS COIE LLP;PATENT-SEA, P.O. BOX 1247, SEATTLE, WA, 98111-1247, US

(73) Assignee: SMART Modular Technologies, Inc., Fremont, CA (US)

(21) Appl. No.: 11/605,809

(22) Filed: Nov. 28, 2006

(51) Int. Cl. H05K 1/14

(52) U.S. Cl. 361/737

(57) ABSTRACT

A dual-channel memory module for use in computing devices is disclosed. The memory module can include a substrate having a base portion, a first connector portion, and a second connector portion spaced apart and electrically insulated from the first connector portion. A first set of memory devices is disposed on the base portion and in electrical communication with the first connector portion, and a second set of memory devices is disposed on the base portion and in electrical communication with the second connector portion. The first and second sets of memory devices are independent of each other.

### TECHNICAL FIELD

The present application relates to multi-channel memory modules for computing devices.

### BACKGROUND

In today's computing devices, memory speed is important for overall system performance. For example, a computing device typically includes a logic processor for manipulating data and random access memory (RAM) for supplying data to the logic processor. If the memory runs slower than the processor, the processor is partially idle during execution, waiting for data to be supplied from the memory. As the processor speed increases, it has become increasingly difficult for the memory to keep up with the processor. Accordingly, there is a need for improving information flow between the processor and the memory to achieve increased overall system performance.

### BRIEF DESCRIPTION OF THE DRAWINGS

FIG. 1 is a block diagram of a computing device having a multi-channel memory module in accordance with an embodiment of the invention.

FIG. 2 is a block diagram showing a portion of the computing device of FIG. 1 configured in accordance with an embodiment of the invention.

FIG. 3 is a block diagram showing a portion of the computing device of FIG. 1 configured in accordance with another embodiment of the invention.

FIG. 4 is a side cross-sectional view illustrating a multi-channel memory module configured in accordance with an embodiment of the invention.

FIG. 5 is a block diagram showing address/control routing of the multi-channel memory module of FIG. 4.

FIG. 6 is a block diagram showing power/ground routing of the multi-channel memory module of FIG. 4.

FIG. 7 is a block diagram showing signal termination of the multi-channel memory module of FIG. 4.

FIG. 8 is a block diagram of a computing device with a multi-channel memory module in accordance with another embodiment of the invention.

FIGS. 9A-B are front and back views illustrating the multi-channel memory module of FIG. 8.

### DETAILED DESCRIPTION

### A. Overview

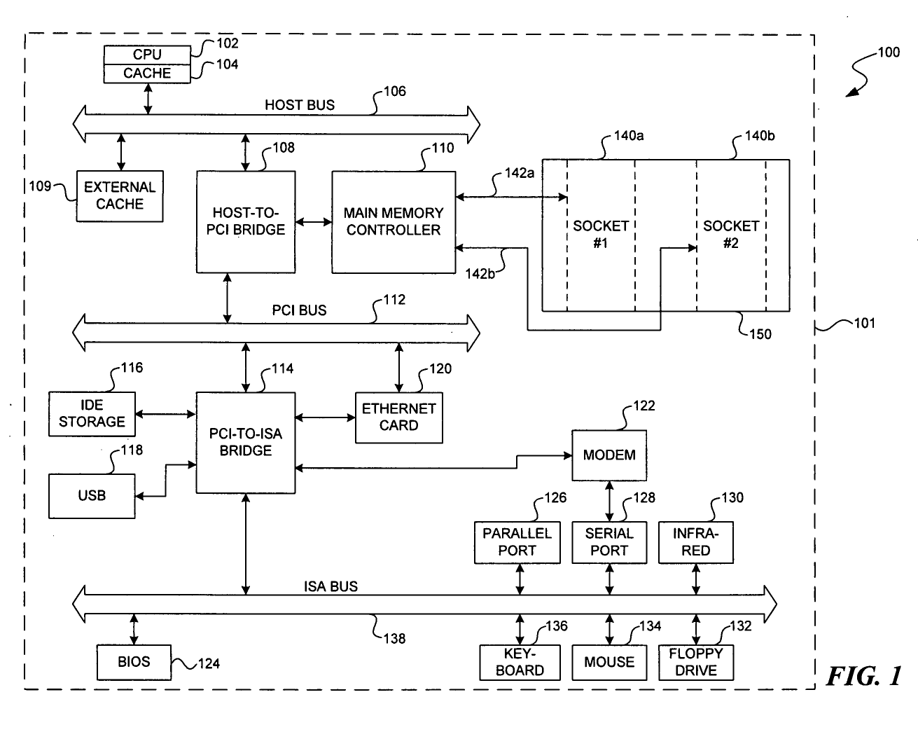

The present disclosure describes devices, systems, and methods for improving memory information flow in a computing device. It will be appreciated that several of the details set forth below are provided to describe the following embodiments in a manner sufficient to enable a person skilled in the relevant art to make and use the disclosed embodiments. Several of the details and advantages described below, however, may not be necessary to practice certain embodiments of the invention. Additionally, the invention can include other embodiments that are within the scope of the claims but are not described in detail with respect to FIGS. 1-9.

### B. Computing System for Improving Memory Access

FIG. 1 illustrates a computing device 100 having a multi-channel memory module 150 for improving memory information flow. The computing device 100 includes a motherboard 101 carrying a central processing unit (CPU) 102. The central processing unit 102 can include an onboard cache 104 connected to a Host bus 106. The central processing unit 102 can include any single-core or dual-core processor including, for example, an Intel® Core™2 Extreme processor manufactured by Intel Corp. of Santa Clara, Calif. The computing device 100 also includes a Host-to-PCI bridge 108 that is in communication with PCI devices such as a memory controller 110 and extended cache 109. The Host-to-PCI bridge 108 relays information between the central processing unit 102 and the PCI devices.

The Host-to-PCI bridge 108 is also connected to a PCI bus 112 that is in communication with a PCI-to-ISA bridge 114. The PCI-to-ISA bridge 114 interfaces with various peripheral devices including, for example, IDE storage 116 (e.g., hard drives), a USB device 118 (e.g., webcams, flash drives, etc.), an Ethernet card 120, and a modem 122. The PCI-to-ISA bridge 114 also interfaces with ISA devices including, for example, a motherboard BIOS 124, a parallel port 126, a serial port 128, an infrared device 130, a floppy drive 132, a mouse 134, and a keyboard 136 via an ISA bus 138. The computing device 100 further includes first and second sockets 140a-b disposed on the motherboard 101. A first bus 142a connects the first socket 140a to the memory controller 110, and a second bus 142b connects the second socket 140b to the memory controller 110.

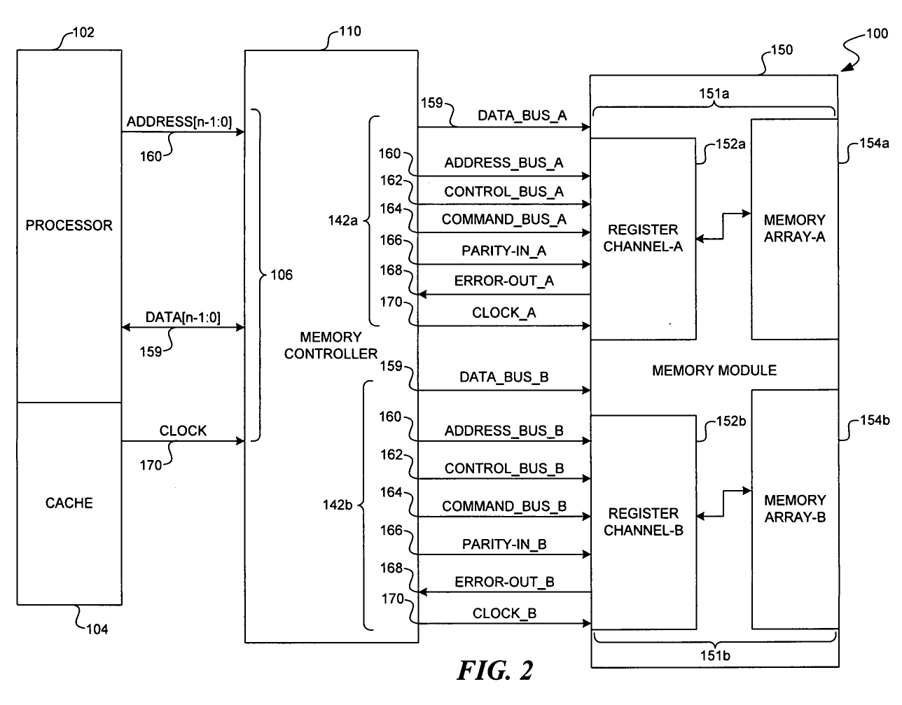

The multi-channel memory module 150 of the computing device 100 interfaces with both the first and second sockets 140a-b. The first and second buses 142a-b provide communication access between the central processing unit 102 and the multi-channel memory module 150. The multi-channel memory module 150 can include multiple memory channels, each of which can be accessed independently from the other, as described in more detail below with reference to FIGS. 2-4.

In operation, data from the peripheral devices (e.g., the IDE storage 116, the USB device 118, and the floppy drive 132) are first loaded into the multi-channel memory module 150 via the PCI bus 112 and/or the ISA bus 138. The central processing unit 102 then directs the memory controller 110 to read or write data from the multi-channel memory module 150 via the first and second buses 142a-b. For example, the central processing unit 102 can direct the memory controller 110 to read from a first channel via the first bus 142a while writing data to a second channel of the multi-channel memory module 150 via the second bus 142b. In another example, the central processing unit 102 can direct the memory controller 110 to read from both the first and second channels of the multi-channel memory module 150.

One expected advantage of the computing device 100 is that the data throughput between the central processing unit 102 and the multi-channel memory module 150 can be doubled without increasing the clock speed of the memory module 150. For example, if the multi-channel memory module 150 is running at a clock speed of 400 MHz, then by having two channels running at the same speed, the total throughput can be doubled from 3.2 GB/s to 6.4 GB/s without increasing the memory clock speed. As the multi-channel memory module 150 delivers more data to the central processing unit 102, the central processing unit 102 can manipulate instructions and data more efficiently to improve overall performance.

Even though the computing device 100 has been illustrated as having various peripheral devices, in certain embodiments, certain peripheral devices can be omitted and other peripheral devices can be incorporated. For example, in some embodiments, the floppy drive 132, the parallel port 126, or other peripheral components in the computing device 100 can be omitted. In other embodiments, the computing device 100 can also include a wireless Ethernet card, a video control card, or other suitable components.

### C. Multi-Channel Memory Module

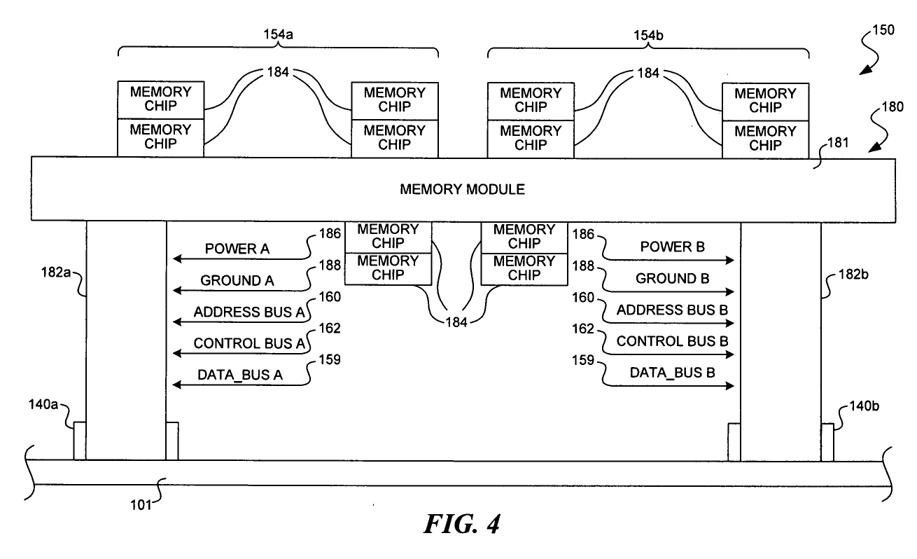

FIG. 2 is a block diagram showing a portion of the computing device 100 in FIG. 1 in more detail and the multi-channel memory module 150 configured in accordance with an embodiment of the invention. As illustrated in FIG. 2, the multi-channel memory module 150 is organized into a first channel 151a and a second channel 151b incorporated into a single form factor. The first channel 151a includes a first register 152a connected to a first memory array 154a, and the second channel 151b includes a second register 152b connected to a second memory array 154b. The first and second registers 152a-b can be configured to buffer command/data signals sent to or coming from the first and second memory arrays 154a-b. The first and second memory arrays 154a-b can each include a plurality of memory chips, as described in more detail below with reference to FIG. 4.

The first and second channels 151a-b are independent of each other (e.g., electrically insulated from each other). As a result, data stored and transmitted via the first channel 151a can be different from those stored and transmitted via the second channel 151b. In one embodiment, the first and second channels 151a-b are generally identical to each other. For example, both the first and second channels 151a-b can include 1 GB of DDR2 memory chips. In other embodiments, the first and second channels 151a-b can be different from each other. For example, the first channel 151a can have 1 GB of DDR2 memory chips while the second channel 151b has 0.5 GB of DDR2 memory chips.

The first bus 142a connects the first channel 151a to the memory controller 110, and the second bus 142b connects the second channel 151b to the memory controller 110. Signals transmitted via the first and second buses 142a-b can include, for example, data 159, address 160, control 162, command 164, parity-in 166, error-out 168, clock 170, or other suitable signals. In the illustrated embodiment, the signals transmitted via both the first and second buses 142a-b are generally identical. In other embodiments, the signals can be different if the first and second channels 151a-b include different types of memory chips. For example, the second bus 142b can also carry clock enable, chip select, data line strobe, or other suitable signals when the second channel 151b includes DDR3 memory chips while the first channel 151a does not.

In operation, the central processing unit 102 directs the memory controller 110 to read or write data from both the first and second channels 151a-b of the multi-channel memory module 150. The central processing unit 102 can transmit signals such as address 160, data 159, and clock 170 to the memory controller 110 via the Host bus 106. The memory controller 110 then accesses both the first and second channels 151a-b as directed as if the first and second channels were separate memory modules. In one embodiment, the memory controller 110 reads data from the first channel 151a via the first bus 142a and writes data to the second channel 151b via the second bus 142b. In other embodiments, the memory controller 110 can read from both the first and second channels 151a-b and transmit all the read data to the central processing unit 102.

One expected advantage of the multi-channel memory module 150 is that the data throughput between the central processing unit 102 and the multi-channel memory module 150 can be increased without altering the layout of the motherboard 101. As illustrated in FIG. 1 and FIG. 2, the first and second buses 142a-b separately connect the first and second sockets 140a-b to the memory controller 110. As a result, the central processing unit 102 can access both channels of the multi-channel memory module 150 at the same time. This layout is generally similar to that in a conventional computing device having two separate memory modules interfacing the first and second sockets 140a-b (FIG. 1). As a result, the central processing unit 102 can access more than one channel of the multi-channel memory module 150 without altering the layout of the motherboard 101 to increase the data throughput.

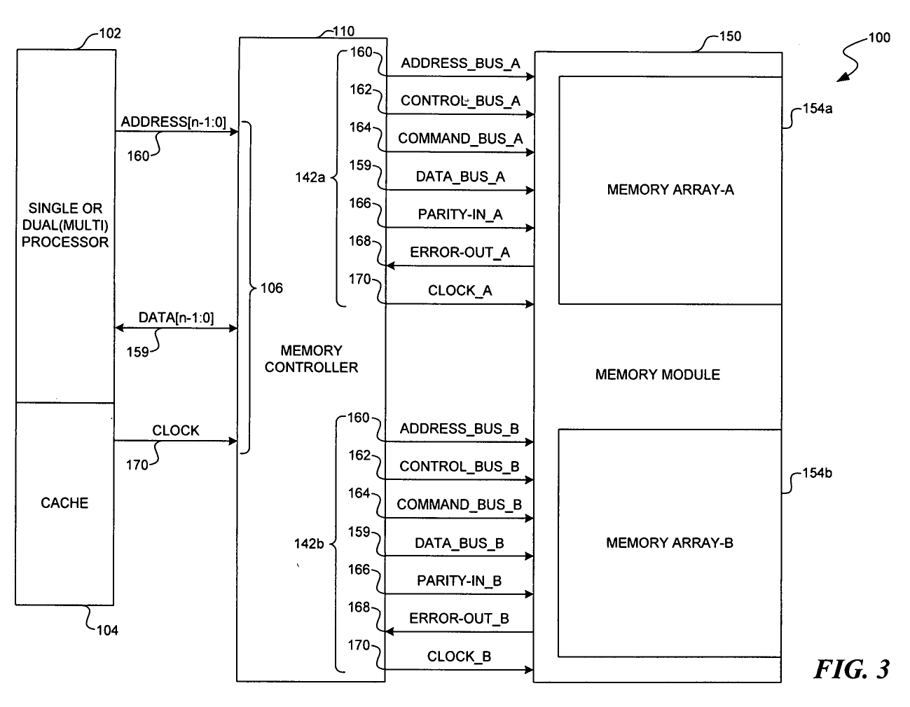

Even though the multi-channel memory module 150 is illustrated as having first and second registers 152a-b in FIG. 2, in certain embodiments, the multi-channel memory module 150 can include unbuffered memory devices. As illustrated in FIG. 3, the first and second buses 142a-b directly connect the memory controller 110 to the first and second memory arrays 154a-b, respectively. Further, in the illustrated embodiment of FIG. 2, the multi-channel memory module 150 includes only two channels 151a-b; in other embodiments, the multi-channel memory module 150 can include three, four, or more channels.

FIG. 4 is a side cross-sectional view illustrating an embodiment of the multi-channel memory module 150 suitable for use in the computing device 100 in FIG. 1. The multi-channel memory module 150 includes a substrate 180 and a plurality of memory chips 184 carried by the substrate 180. The memory chips 184 can be divided into the first and second memory arrays 154a-b. The memory chips 184 can be stacked or singularly disposed on the substrate 180. The memory chips 184 can include multiple memory chips stacked vertically, as illustrated in FIG. 4, or die level stacks in the same package. The memory chips 184 can include DRAM, SDRAM, SRAM, DDR1, DDR2, DDR3, RLDRAM, FCRAM, Flash memory, Synchronous Flash memory, or other types of memory devices.

The substrate 180 can include a base portion 181 and first and second connector portions 182a-b extending transversely from the base portion 181. The base portion 181 can include a printed circuit board for carrying the memory chips 184 and interconnecting circuits (not shown). The first and second connector portions 182a-b can each include a printed circuit board attached to the base portion 181. The first and second connector portions 182a-b can be attached to the base portion 181 using a solder, glue, a mechanical fastener (e.g., clips, nuts, and bolts, etc.), or other suitable fasteners.

The first and second connector portions 182a-b can include electrical terminals (not shown) or other interfacing devices to interface with the first and second sockets 140a-b on the motherboard 101. The first connector portion 182a corresponds to the first channel 151a, and the second connector portion 182b corresponds to the second channel 151b. In certain embodiments, the first and second connector portions 182a-b are electrically insulated from each other. In other embodiments, the first and second connector portions 182a-b can share certain electrical connections, e.g., power, ground, command, or other suitable common connections.

The first and second channels 151a-b can be accessed generally similarly during operation. Accordingly, the following description of the first channel 151a also applies to the second channel 151b. In operation, the first connector portion 182a can contact the first socket 140a to establish a bus for power 186, ground 188, address 160, control 162, or any other signals transmitted between the first channel 151a and other components of the computing device 100. For example, the central processing unit 102 can access the first channel 151a via the first socket 140a and the first bus 142a. Then, the central processing unit 102 can transmit signals, such as address 160 and control 162, via the motherboard 101 and the interface between the first connector portion 182a and the first socket 140a.

One expected advantage of using the multi-channel memory module 150 is the real estate saving on the motherboard 101. In conventional computing devices, the memory modules are typically vertically inserted into the first and second sockets 140a-b. The inserted memory modules extend from the motherboard 101 to occupy a space generally corresponding to the height of the memory modules. By positioning the base portion 181 of the multi-channel memory module 150 generally parallel to the motherboard 101, the space occupied by the memory module 150 corresponds generally to the thickness of the memory module 150 (plus some clearance), not the height of the memory module 150. As a result, the amount of extension into the space above the motherboard 101 is reduced, and the amount of space required to accommodate the memory module 150 is decreased.

Another expected advantage of using the multi-channel memory module 150 is the reduction in manufacturing cost for the computing device 100. According to conventional technique, two memory modules are typically inserted into the first and second sockets 140a-b. Each memory module would incur a certain amount of manufacturing time, testing time, and material cost. Thus, by having a single memory module with multiple channels, manufacturing cost can be reduced without sacrificing memory functionality.

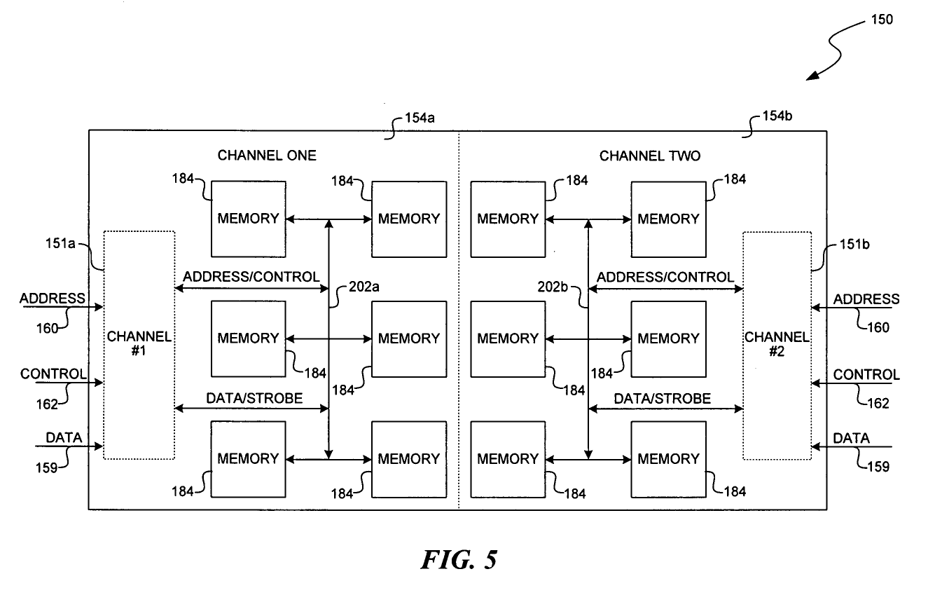

FIGS. 5-7 illustrate signal routing and termination of the multi-channel memory module 150 of FIG. 4. As illustrated in FIG. 5, a first address/control routing network 202a distributes the address 160 and control 162 signals coming into the first connector portion 182a into individual memory chips 184 in the first channel 151a. A second address/control routing network 202b distributes the address 160 and control 162 signals coming into the second connector portion 182b into individual memory chips 184 in the second channel 151b. The first and second address/control routing networks 202a-b are independent of and insulated from each other.

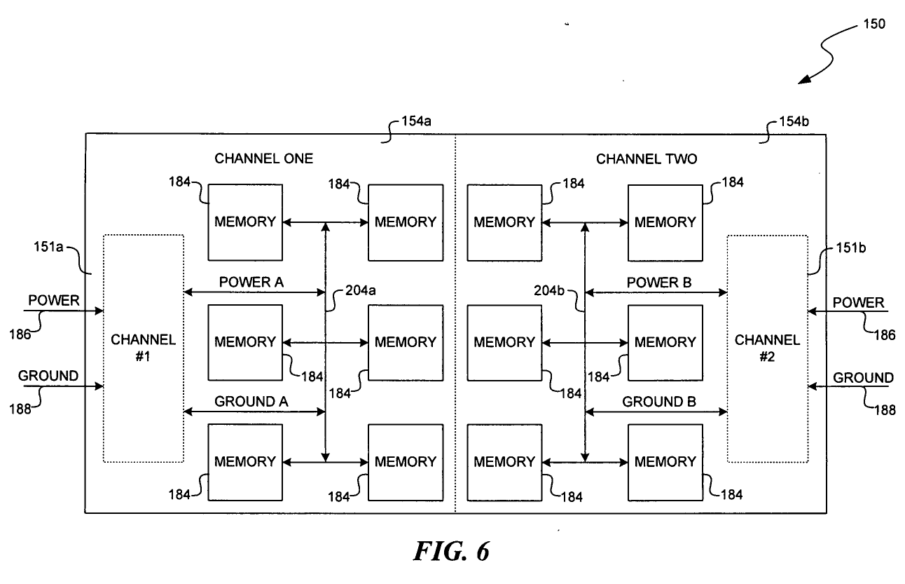

Similarly, as illustrated in FIG. 6, a first power/ground routing network 204a distributes the power 186 and ground 188 signals coming into the first connector portion 182a into individual memory chips 184 in the first channel 151a. A second power/ground routing network 204b distributes the power 186 and ground 188 signals coming into the second connector portion 182a into individual memory chips 184 in the second channel 151b. The first and second power/ground routing networks 204a-b are independent of and insulated from each other.

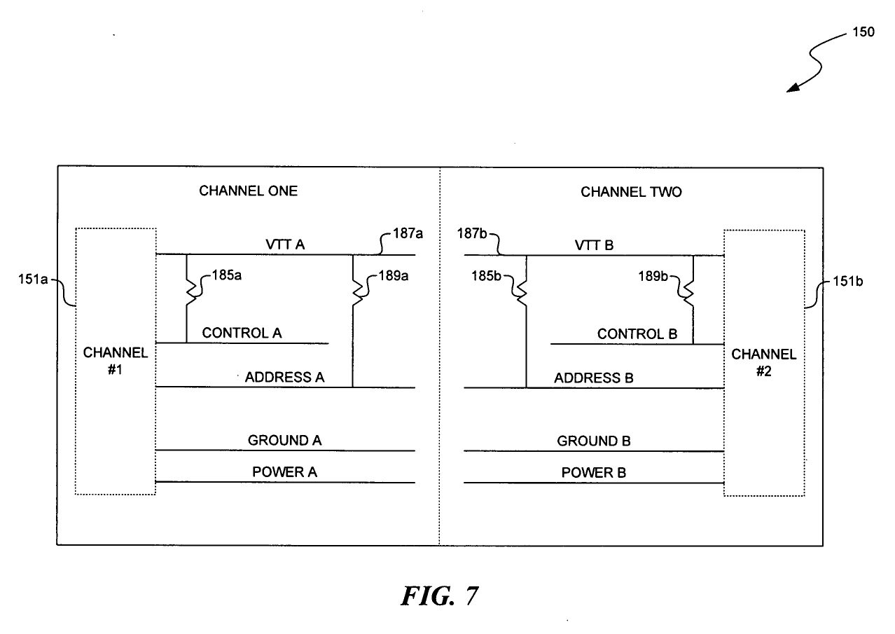

As illustrated in FIG. 7, each of the address and control signals in the first channel 151a can be terminated to a termination line 187a at a termination voltage of Vtt using terminating resistors 185a, 189a. Each of the address and control signals in the second channel 151b can be terminated to a second termination line 187b using terminating resistors 185b, 189b. The termination voltage Vtt can be generated on the motherboard 101 (FIG. 1) and supplied to the memory module 150 via a dedicated connection (e.g., pin(s)). The termination voltage Vtt can also be generated internally in the memory module 150, for example, by using a resistor divider connected to a module voltage (e.g., Vcc, Vdd), or by using a voltage divider integrated circuit. In one embodiment, the first and second termination lines 187a-b are separate from each other. In other embodiments, the first and second termination lines 187a-b can be a common line.

### C. Additional Computing System Having Multi-Channel Memory Modules

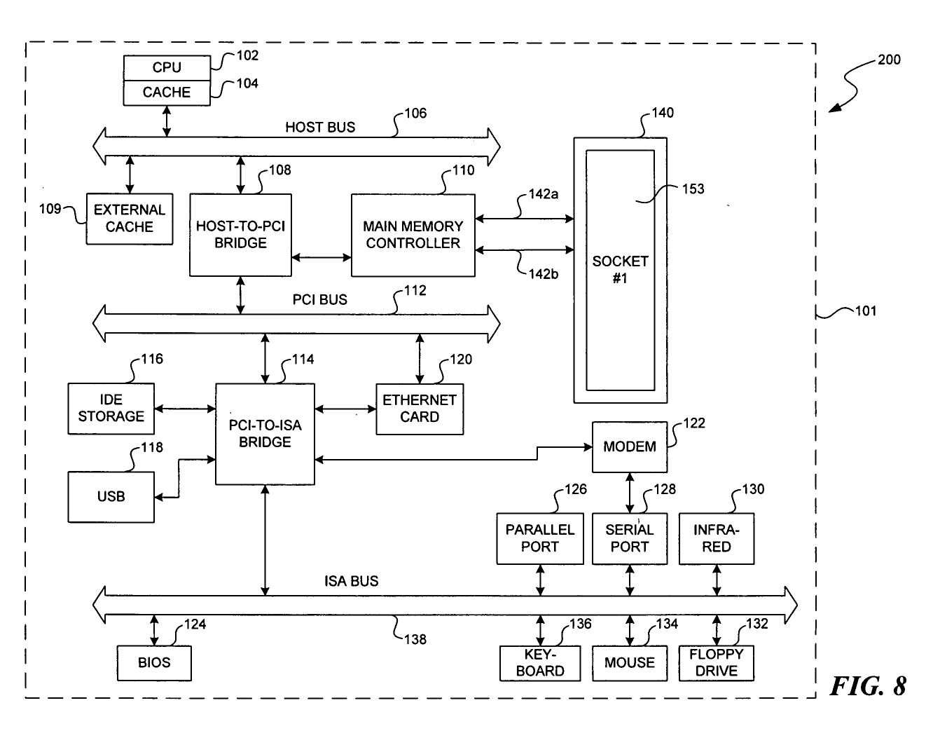

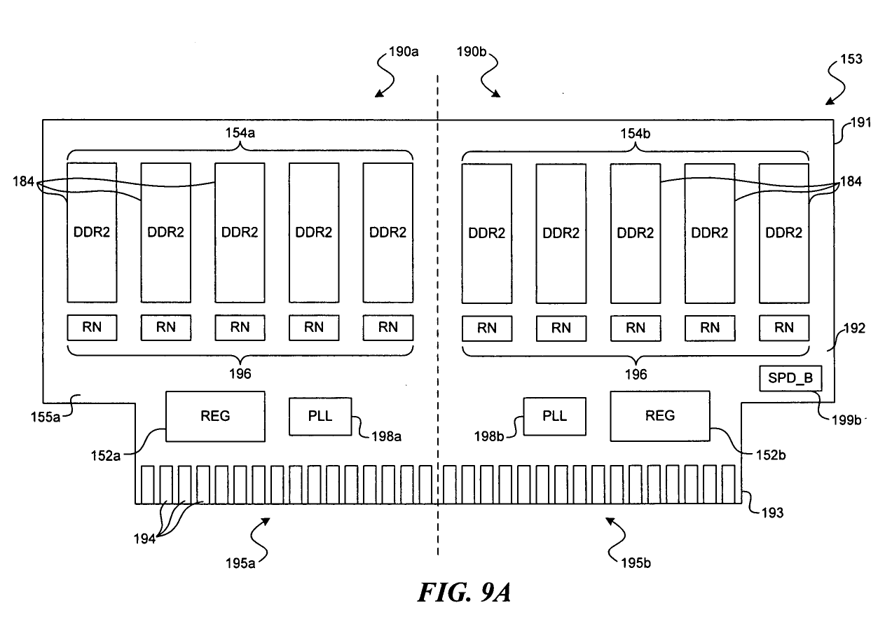

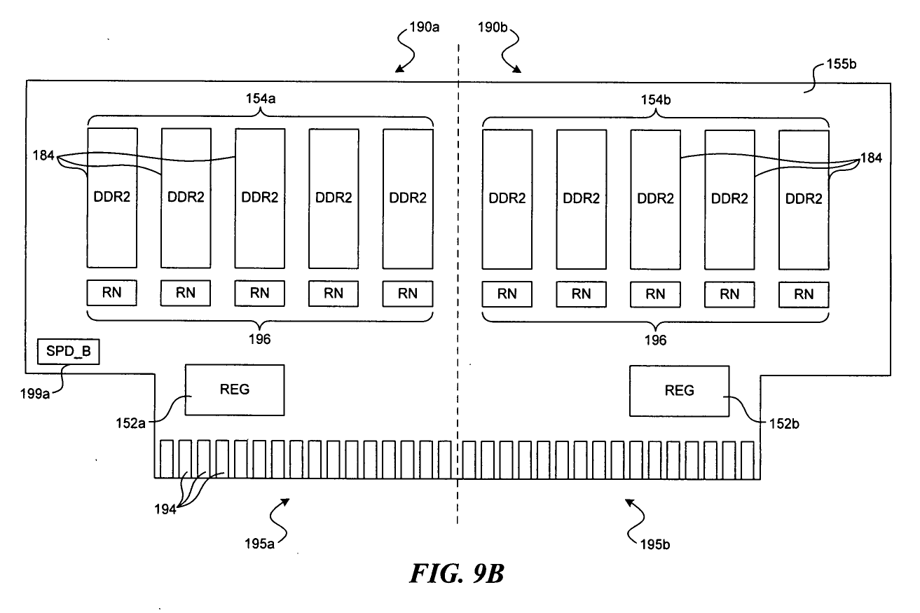

FIG. 8 is a block diagram of a computing device 200 having a multi-channel memory module 153 in accordance with another embodiment of the invention. Several components of the computing device 200 are similar to those of the computing device 100. As such, like reference symbols refer to like features and components in FIGS. 1-5. The computing device 200 can be configured generally similarly to the computing device 100 in FIG. 1 except that the first and second buses 142a-b are connected to only a single socket 140 interfacing the multi-channel memory module 153. The multi-channel memory module 153 is configured to be inserted into the socket 140 in a way similar to a conventional memory module, as described in more detail below with reference to FIGS. 9A-B.

FIG. 9A is a front view and FIG. 9B is a back view of an embodiment of the multi-channel memory module 153 of FIG. 8. The multi-channel memory module 153 includes a substrate 191 having a base portion 192 and a connector portion 193 extending laterally from the base portion 192. The base portion 192 and the connector portion 193 can be formed from a printed circuit board or other suitable substrate materials. The connector portion 193 can include a plurality of conductive connectors 194 for carrying power, data, address, control, command, Vtt, or other types of data.

The multi-channel memory module 153 is arranged into a first channel 190a and a second channel 190b. Each of the first and second channels 190a-b includes a plurality of memory chips 184 (shown as DDR2 memory devices though other types of memory devices can also be used), corresponding termination resistors 196, first and second registers 152a-b, phase lock loop modules 198a-b, and serial presence detect modules 199a-b. In one embodiment, a first portion 195a of the connectors 194 is connected to the first register 152a and associated first memory array 154a, and a second portion 195b of the connectors 194 is connected to the second register 152b and associated second memory array 154b. In another embodiment, the connectors 194 located at the front side 155a of the multi-channel memory module 153 are connected to the first register 152a and associated first memory array 154a, and those located on the back side 155b of the multi-channel memory module 153 are connected to the second register 152b and associated second memory array 154b.

Referring to FIGS. 8 and 9 together, in operation, the connectors 194 can contact the socket 140 to establish a connection for the first and second channels 190a-b of the memory module 153. The central processing unit 102 can then access the first and second channels 190a-b via the first and second buses 142a-b between the memory controller 110 and the socket 140. In one embodiment, the central processing unit 102 can read/write using the first and second channels 190a-b simultaneously. In other embodiments, the central processing unit 102 can read one channel while writing to the other.

One expected advantage of using the multi-channel memory module 153 is the increased throughput from a single socket on a motherboard. In conventional devices, the central processing unit can typically access only one memory module in a particular socket. As a result, the throughput from the socket is limited by the speed of the memory module in that socket. Thus, by having two channels communicating with the central processing unit at the same time, the throughput from the socket is increased.

Even though the memory module 153 is shown to include the memory chips 184 are connected to the first and second registers 152a-b, in other embodiments, the memory module 153 can be unbuffered, as described above with reference to FIG. 3. Further, the memory module 153 can include other components in addition to or in lieu of the components shown in FIG. 9A-B. For example, in certain embodiments, the memory module 153 can also include thermal sensors (not shown) for detecting the operating temperature of the memory module 153.

Unless the context clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also include the plural or singular number, respectively. When the claims use the word “or” in reference to a list of two or more items, that word covers all of the following interpretations of the word: any of the items in the list, all of the items in the list, and any combination of the items in the list.

The above detailed descriptions of embodiments of the invention are not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while steps are presented in a given order, alternative embodiments may perform steps in a different order. The various embodiments described herein can be combined to provide further embodiments.

In general, the terms used in the following claims should not be construed to limit the invention to the specific embodiments disclosed in the specification, unless the above detailed description explicitly defines such terms. While certain aspects of the invention are presented below in certain claim forms, the inventors contemplate the various aspects of the invention in any number of claim forms. Accordingly, the inventors reserve the right to add additional claims after filing the application to pursue such additional claim forms for other aspects of the invention.

I/We claim:

1. A dual-channel memory module, comprising:
a substrate having a base portion, a first connector portion, and a second connector portion spaced apart and electrically insulated from the first connector portion;
a first set of memory devices disposed on the base portion and in electrical communication with the first connector portion; and
a second set of memory devices disposed on the base portion and in electrical communication with the second connector portion, wherein the first and second sets of memory devices are independent of each other.

2. The dual-channel memory module of claim 1 wherein the first and second connector portions transversely extend from the base portion.

3. The dual-channel memory module of claim 1 wherein the first and second connector portions extend from and are co-planar with the base portion.

4. The dual-channel memory module of claim 1 wherein the substrate includes a printed circuit board.

5. The dual-channel memory module of claim 1, further comprising a first bus connecting the first connector portion and the first set of memory devices and a second bus connecting the second connector portion and the second set of memory devices.

6. The dual-channel memory module of claim 5 wherein the first bus is independent of and electrically insulated from the second bus.

7. The dual-channel memory module of claim 1 wherein the substrate includes a first surface and a second surface, and wherein the first and second sets of memory devices are disposed on both the first and second surfaces.

8. The dual-channel memory module of claim 1 wherein the substrate includes a first surface and a second surface, and wherein the first set of memory devices and the first connector portion are disposed on the first surface and the second set of memory devices and the second connector portion are disposed on the second surface.

9. The dual-channel memory module of claim 1 wherein the first and/or second sets of memory devices include stacked memory devices.

10. The dual-channel memory module of claim 1 wherein the first set of memory devices is identical to the second set of memory devices.

11. The dual-channel memory module of claim 1 wherein the first set of memory devices is different from the second set of memory devices.

12. The dual-channel memory module of claim 1 wherein the first and second sets of memory devices are selected from a group consisting of DRAM, SDRAM, SRAM, DDR1, DDR2, DDR3, RLDRAM, FCRAM, Flash memory, and Synchronous Flash memory.

13. A computing device incorporating the dual-channel memory module of claim 1 and further including a motherboard carrying a processor, a memory controller, and a socket configured to receive the dual-channel memory module.

14. A computing device, comprising:
a motherboard carrying a processor;
first and second memory controllers disposed on the motherboard and electrically connected with the processor;
a memory socket disposed on the motherboard and receiving a dual-channel memory module; and
a bus electrically connecting both the first and second memory controllers to the memory socket such that the processor, the first and second memory controllers, and the dual-channel memory module are in electrical communication.

15. The computing device of claim 14 wherein the dual-channel memory module includes a base portion, first and second connector portions extending from and co-planar with the base portion, and first and second sets of memory devices electrically connected to the first and second connector portions, respectively.

16. The computing device of claim 15 wherein the first and second connector portions of the dual-channel memory module are electrically insulated from each other.

17. The computing device of claim 15 wherein the base portion of the dual-channel memory device includes a first surface and a second surface, and wherein the first set of memory devices is disposed on the first surface and the second set of memory devices is disposed on the second surface.

18. A method for processing data in a computing device, comprising:
loading data from a storage medium into a single memory module having a first channel and a second channel independent of the first channel;
moving the loaded data to a memory controller from both the first channel and the second channel of the memory module; and
transferring the data from the memory controller to a processor for calculation.

19. The method of claim 18 wherein moving the loaded data to a memory controller includes moving the loaded data to a memory controller via a common bus between the controller and the memory module.

20. The method of claim 18, further comprising reading data from the memory module via the first channel while writing data to the memory module via the second channel.
